(19) United States
(12) Patent Application Publication
(10) Pub. No.: US 2005/0183882 A1
(43) Pub. Date: Aug. 25, 2005

(54) Multi-layer circuit board with thermal diffusion and method of fabricating the same

(76) Inventors: Young Yun, Gyeonggi-do (KR); Byun-Se So, Gyeonggi-do (KR); Young-Man Ahn, Gyeonggi-do (KR); You-Keun Han, Gyeonggi-do (KR)

Correspondence Address: MYERS BIGEL SIBLEY & SAJOVEC, PO BOX 37428, RALEIGH, NC, 27627, US

(21) Appl. No.: 11/048,678

(22) Filed: Feb. 1, 2005

(30) Foreign Application Priority Data
Feb. 23, 2004 (KR) 10-2004-0011779

(51) Int. Cl. H05K 1/00; H01L 21/4763

(52) U.S. Cl. 174/250

(57) ABSTRACT

A multi-layer circuit board having an improved heat spreading performance is described. In a multi-layer circuit board structure configured such that insulating layers and interconnection conductive layers are alternately stacked, the interconnection conductive layers include a top interconnection conductive layer having a main surface on which circuit elements are mounted, a bottom interconnection conductive layer as a bottom surface layer facing the top interconnection conductive layer, an inner power conductive layer having a predetermined thickness, disposed between the top interconnection conductive layer and the bottom interconnection conductive layer, with some of the insulating layers interposed between the top and bottom interconnection conductive layers. The interconnection conductive layers can be of various thicknesses to facilitate heat diffusion. Heat diffusion can be accomplished with variations in thickness of either the insulating layers or electrically conductive layers. Heat diffusion performance is improved in comparison with a conventional circuit board assembly, thereby minimizing or reducing sizes of elements of a heat diffuser, or omitting the installation of a heat diffuser.

### CROSS-REFERENCE TO RELATED APPLICATION

This application claims the priority benefit of Korean Patent Application No. 2004-11779, filed on Feb. 23, 2004, the disclosure of which is hereby incorporated herein by reference in its entirety.

### BACKGROUND

1. Technical Field

The present invention relates to a printed circuit board (PCB), and more particularly, to a multi-layer circuit board structure and a method of fabricating the same.

2. Discussion of Related Art

Generally, multi-layer circuit boards are widely used in electronic systems such as personal computers, or the like. The multi-layer circuit boards provide advantages over single-layer circuit boards. For example, the advantages include increased efficiency in the usage of space, and a reduction in overall physical size. The multi-layer circuit board has an electronic circuit element such as a microprocessor, a capacitor or the like, as well as a semiconductor memory device such as a DRAM or the like mounted thereon, so as to provide a multi-chip module.

The heat generated from such a multi-layer circuit board has increased due to trends of higher speeds and higher capacitances of the electronic system. If the heat generated from the multi-layer circuit board cannot be rapidly dissipated, the temperature of the electronic components may increase. With a sufficient rise in temperature there may be an operational failure, or the performance of the system may deteriorate. Previously a heat diffuser or a heat spreader or the like was installed on the conventional multi-layer circuit board to facilitate diffusion and dissipation of heat. However, the use of these heat diffusers in connection with the multi-layer circuit board used considerable space. The heat diffusers reduced the space available for placement of components and also limited space for signal routing.

The heat generated from the conventional multi-layer circuit board and problems caused by the installation of the heat diffuser or spreader are explained below in more detail with reference to the drawings.

First, FIGS. 1A and 1B illustrate the structure of a multi-chip module in which a heat diffuser is installed in a typical multi-layer circuit board. A circuit element 25, such as a capacitor, semiconductor integrated circuit chips 20, 21 mounted on the board 10 via solder bumps 23,24 and a heat spreader 40 are mounted on a multi-layer circuit board 10. In FIG. 1A, the mounting structure illustrates a section of the multi-layer circuit board 10 in the narrow dimension thereof. The mounting structure in FIG. 1B illustrates only an upper portion of the multi-layer circuit board 10 in a longitudinal direction thereof.

The multi-layer circuit board 10 shown in FIGS. 1A and 1B may have a multi-layer structure as shown in FIGS. 2 and 3. FIG. 2 illustrates an example of the layer structure of the multi-layer circuit board such as disclosed in U.S. Pat. No. 5,764,491, in which the multi-layer circuit board includes a component layer 11, a VDD layer 13, an insulating layer 15, and a ground layer 17.

FIG. 3 illustrates an example of a multi-layer circuit board such as disclosed in U.S. Pat. No. 6,175,088, in which power, ground, and routing layers 101-104 are separated by an insulating layers 105. Here, on the outer layers 101, electronic circuit components are capable of being mounted. The power layers 102 and the ground layers 103 function to supply power and ground to the mounted electronic circuit components. The signal routing conductive layers 104 and the power and ground supply conductive layers 102, 103 are disposed inside relative to the outer layers 101, and thus, they are referred to as inner layers.

The thicknesses of the inner layers of FIG. 3 are as relatively shown in FIG. 4. FIG. 4 is a view illustrating the layer structure of the multi-layer circuit board of FIG. 1, in which the inner layers 102a, 103a, 105a, 107a disposed between outer layers 101a, 108a generally have the same thickness, and may be composed of the same material, for example, copper. The insulating layers 201a, 202a, 203a, 204a for insulating the above layers may be composed of prepreg layers, and their thicknesses can be adjusted during design or fabrication in order to assure desired electrical characteristics such as impedance, or the like, and meet the predetermined total thickness of the assembled multi-layer circuit board.

FIGS. 5A and 5B are views illustrating eight-layer and ten-layer stack structures respectively of FIG. 4. In FIG. 5A, conductive layer or conducting layer 101a functions as a top interconnection conductive layer having a main surface on which circuit elements are to be mounted, and conductive layer 108a functions as a bottom interconnection conductive layer with a surface layer facing the top interconnection conductive layer 101a. Each of inner conductive layers 102a, 103a, 104a, 105a, 106a, 107a may be an inner power conductive layer or an inner signal routing conductive layer. The inner power conductive layer is disposed by interposing some of insulating layers of 201a˜207a between the top interconnection conductive layer 101a and the bottom interconnection conductive layer 108a. The inner signal routing conductive layer is disposed by interposing some other insulating layers 201a˜207a between the top interconnection conductive layer 101a and the bottom interconnection conductive layer 108a. The eight conductive layers L1˜L8 are composed of e.g. copper layers, e.g. each having a thickness of about 18 μm.

In the case of a ten-layered stack structure as shown in FIG. 5B, ten conductive layers L1-L10 separated by a corresponding insulating layer are formed such that each layer has the same thickness.

In Japanese Laid Open Publication No. 2001-53421, there is disclosed a smoothing printed substrate in which a small current signal circuit and a large current signal circuit are integrated to facilitate compactness, high reliability, and low price of the resultant device. However, the structure does not optimize heat diffusion performance for the substrate in formation of a multi-chip module because conductive layers have steps in the height. The thickness of one layer is substantially equal to the thickness of other like layers.

With the structures shown in FIGS. 4, 5A and 5B, operation failure or performance deterioration of a multi-chip module can occur since heat cannot be rapidly and evenly dissipated during operation of a multi-chip module, in the case of the multi-chip module (or memory system) as shown in FIG. 1. As heat is discharged from semiconductor integrated circuit chips 20, 21 and a circuit component 25 in FIG. 1, the heat is transmitted to a multi-layer circuit board 10 through conductive lines therein. In this case, since heat diffusion efficiency through the multi-layer circuit board 10 may be very low, tape 30 having a good heat diffusion property is attached to the assembly, and a heat diffuser or spreader 40 is installed on top of the board. However, the heat diffusion using the heat diffuser causes other problems. The installation and connection of the heat diffuser to the multi-layer circuit board uses valuable space. This results in enlarging the size of a multi-chip module or the resulting electronic system. In addition, the use of this type of heat diffuser creates the problem of further separating components and complicating signal routing. The arrangement of components and/or the signal routing cannot be easily or efficiently achieved due to the installation of the heat diffuser both increasing their size and limiting accessibility.

### SUMMARY OF THE INVENTION

The present invention is directed to provide a multi-layer circuit board structure and a method of fabricating the same. Embodiments of the present invention substantially obviate one or more problems due to limitations and disadvantages of the related art.

An object of some embodiments of the present invention is to provide a multi-layer circuit board structure for minimizing or reducing the size of an external heat diffuser.

Still another object of some embodiments of the present invention is to provide a multi-layer circuit board structure, in which its heat spreading performance is significantly improved compared with a conventional one.

Further embodiments of the present invention provide a multi-layer circuit board structure and a method of fabricating the same for effectively realizing heat spreading without an installation of an external heat spreader.

Further, some embodiments of the present invention provide an improved structure of a multi-layer circuit board and a method of fabricating the same for maximizing or improving a heat diffusion efficiency without the addition of an extra or external heat spreading layer.

Some exemplary embodiments of the present invention provide a multi-layer circuit board structure configured such that insulating layers and interconnection conductive layers are alternately stacked, in which among the interconnection conductive layers, inner interconnection conductive layers, which are disposed under an outer interconnection conductive layer having a main surface on which circuit elements are capable of being mounted, have different thicknesses.

In further embodiments of the multi-layer circuit board structure, the insulating layers may be composed of prepreg layers, and the interconnection conductive layers may be composed of copper layers. Further, the inner interconnection conductive layers may comprise power conductive layers and signal routing conductive layers, and preferably, the thickness of the conductive layer is greater than that of the signal routing conductive layer. In some embodiments of the multi-layer circuit board structures the inner insulating layers may be of varying thicknesses to improve heat diffusion.

In other embodiments the thickness of the signal routing conduction layer is greater than that of a power conduction layer. In accordance with an exemplary embodiment, the present invention provides a method of fabricating a multi-layer circuit board configured such that insulating layers and interconnection conductive layers are alternately stacked, in which some of the inner interconnection conductive layers between the outer layers are formed thicker than those of the rest of the inner interconnection conductive layers, thereby improving the heat diffusing performance of the multi-layer circuit board.

According to some embodiments of the invention, a multi-layer circuit board structure and a method of fabricating the same, the heat spreading performance is significantly improved compared with a conventional structure, thereby providing advantages of minimizing or reducing sizes of an external heat diffuser, or omitting the installation of an external heat diffuser.

### BRIEF DESCRIPTION OF THE DRAWINGS

The above and other features and advantages of the present invention will become more apparent to those of ordinary skill in the art by describing in detail preferred embodiments thereof with reference to the attached drawings in which:

FIGS. 1A and 1B are diagrams illustrating a multi-chip module in which a heat diffuser is installed on a typical multi-layer circuit board;

FIGS. 2 and 3 are diagrams illustrating examples of layer structures of a conventional multi-layer circuit board;

FIG. 4 is a diagram illustrating a layer structure of the multi-layer circuit board of FIG. 1;

FIGS. 5A and 5B illustrate eight-layer and ten-layer stack structures respectively of FIG. 4;

FIG. 6 illustrates a layer structure of a multi-layer circuit board according to an embodiment of the present invention;

FIGS. 7A and 7B illustrate eight-layer and ten-layer stack structures respectively of FIG. 6; and

FIG. 8 is a graph of experimental data comparing component temperatures during tests of structures illustrated by FIGS. 6 and 4.

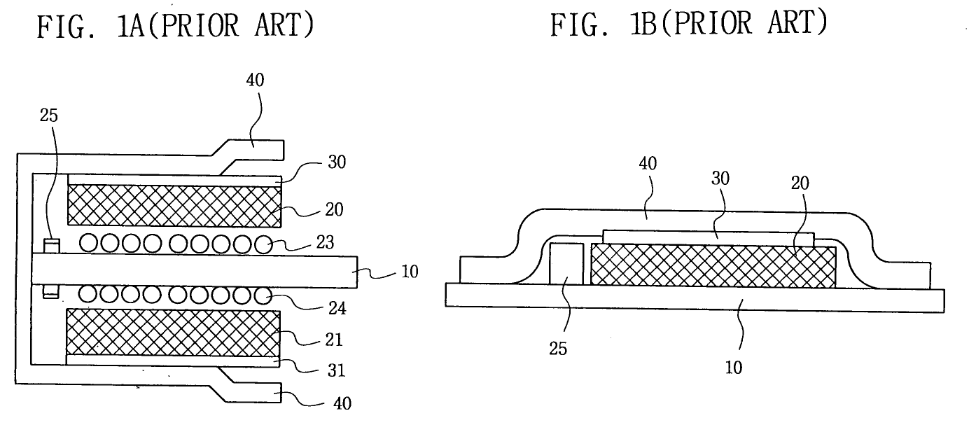

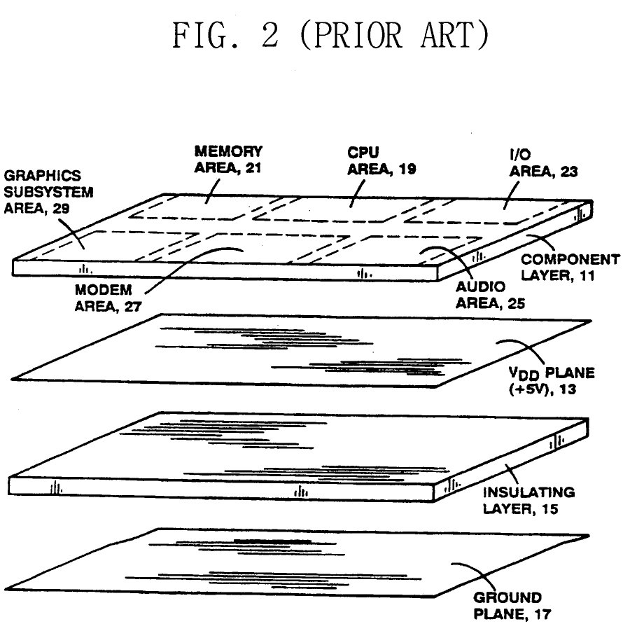

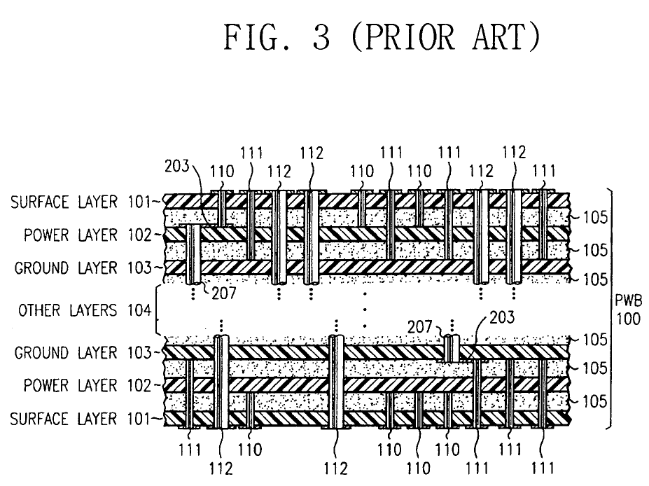

### DETAILED DESCRIPTION OF THE INVENTION

The present invention now will be described more fully hereinafter with reference to the accompanying drawings, in which embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout. As used herein the term “and/or” includes any and all combinations of one or more of the associated listed items.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in the Figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Embodiments of the present invention are described herein with reference to cross-section (and/or plan view) illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an etched region illustrated or described as a rectangle will, typically, have rounded or curved features. Thus, the regions illustrated in the figures are schematic in nature and their shapes are not intended to illustrate the precise shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will also be appreciated by those of skill in the art that references to a structure or feature that is disposed “adjacent” another feature may have portions that overlap or underlie the adjacent feature.

As used herein the term “conductive” or “conducting” refers to elements (such as a conductive layer in a multi-layer circuit board) where an impedance associated therewith is substantially given by the relationship of Impedance=V/I, where V is a voltage across the element and I is the current, at substantially all expected operating frequencies (i.e., the impedance associated with the element is substantially the same at all operating frequencies).

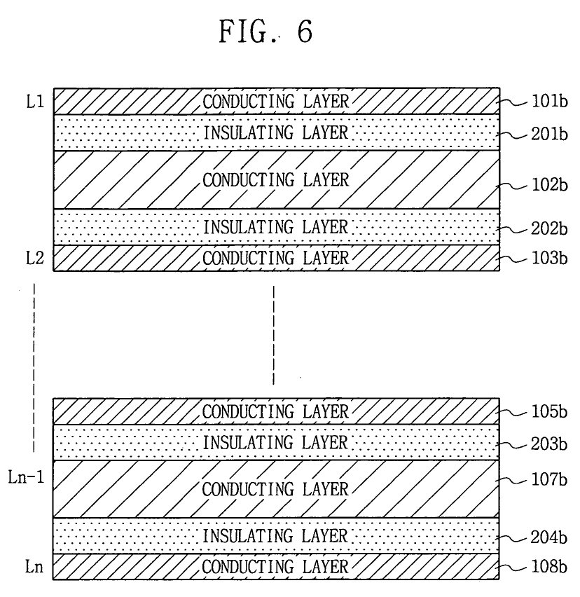

FIG. 6 illustrates the layer structure of the multi-layer circuit board according to some embodiments of the present invention. Conductive layers 101b, 102b, 103b, 105b, 107b, 108b are separated by insulating layers 201b, 202b, 203b, 204b. Inner layers 102b, 103b, 105b, 107b among the conductive layers are disposed between the outer layers 101b and 108b. As shown in the drawing, the inner layers 102b, 103b have thicknesses that are different from layers 101, 103 and may have thicknesses that are different from one another. Inner layers 107b and 105b can be formed with different thicknesses. Here, the outer layers 101b, 108b and the inner layers 102b, 103b, 105b, 107b can be composed of the same material, for example, copper. The insulating layers 201b, 202b, 203b, 204b, which insulate the inner conductive layers, may be composed of a material intended to assure electrical characteristics such as impedance, or the like. The thickness of each layer of the insulation layers may be adjusted during design or fabrication to meet the desired total thickness of the multi-layer circuit board, and may be, for example, a prepreg layer.

During design of the PCB, the total number of layers is determined. The number of layers is predetermined by the nature of the use of or purpose of the PCB. In one embodiment of the invention, the designer may use that predetermined number of layers and utilize other aspects of the invention. For example, should space constraints allow, the designer may increase the relative thickness of certain layers compared to other layers while maintaining the predetermined number of layers.

In n layers (n is a natural number greater than 2) of the multi-layer circuit board as shown in FIG. 6, an outer layer, a first inner layer, and a second inner layer, composed of the same material as the first inner layer, can be formed as a stack structure. For example the first inner layer and the second inner layer can be formed with different thickness. Here, the outer layer, the first inner layer, and the second inner layer are preferably composed of a conductive material in order to improve thermal diffusion. Alternately, they can be composed of an non-conductive material or may be the prepreg layers. For example, in the case that the first inner layer 102b is used as a power conductive layer for transmitting a power voltage or a ground voltage, and the second inner layer 103b is used as a signal routing layer for transmitting an input/output signal or an inner signal of an embedded circuit element, the thickness of the first inner layer 102b is preferably thicker than that of the second inner layer 103b in terms of having greater thermal diffusion.

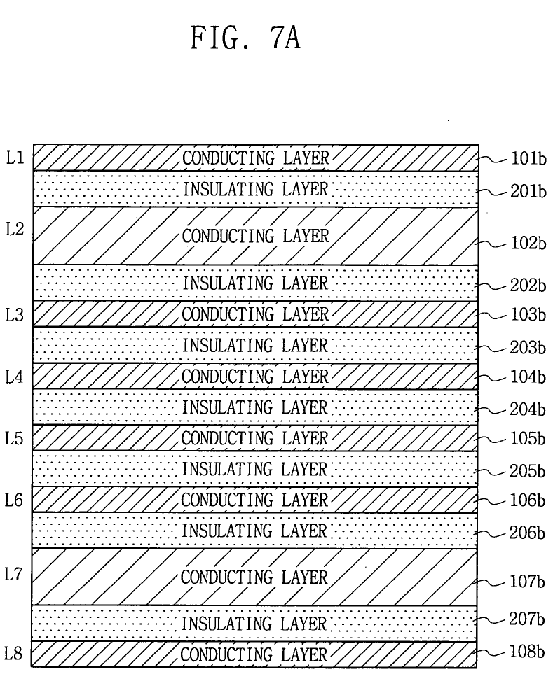

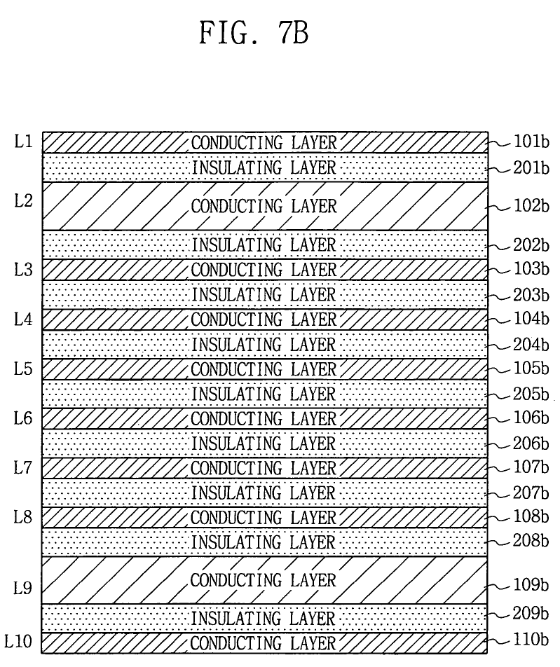

FIGS. 7A and 7B illustrate eight and ten laminated layer structures respectively in accordance with the example of FIG. 6. In FIG. 7A, a conductive layer 101b can be used as a top interconnection conductive layer as a main surface, on which circuit elements are mounted, and a conductive layer 108b can be used as a bottom interconnection conductive layer as a bottom surface layer facing the top interconnection conductive layer 101b. Here, the top and bottom interconnection conductive layers 101b, 108b are outer surface layers.

Inner conductive layers 102b, 103b, 104b, 105b, 106b, 107b may be inner power conductive layers and/or an inner signal routing conductive layers. The inner power conductive layers are disposed between the top interconnection conductive layer 101b and the bottom interconnection conductive layer 108b with some of insulating layers 201b˜207b interleaved between them. That is, the inner power conductive layer 102b is disposed over the inner signal routing conductive layer 103b with the insulating layer 202b interposed between them, and the inner power conductive layer 107b is disposed under the inner signal routing conductive layer 106b with the insulating layer 206b interposed between them. In this example, the multi-layer circuit board has a symmetric structure about the insulating layer 204b. In one embodiment, among the eight conductive layers L1˜L8, the conductive layers except the conductive layers L2, L7 may be composed of copper laminating layers having a thickness of about 18 μm, and the conductive layers L2, L7 may be composed of copper laminating layers having a thickness of about 52 to 108 μm.

Further, in the example of the ten-layered stack structure shown in FIG. 7B, conductive layers L2, L9 are formed thicker than the other conductive layers among the ten conductive layers L1˜L10. The minimum thickness of layers 102b and 109b are greater than the minimum thickness of the other inner conductive layers 103b-108b. As such, in the embodiments of the present invention, some predetermined inner layers among the all inner layers are formed thicker than others, so that the heat generated from the mounted electronic parts can be spread rapidly through the thicker inner conductive layers. Thus, problems of temperature increase, which are caused in multi chip modules, memory systems, or the like, can be significantly minimized or eliminated by greatly improving the thermal diffusion.

As described above, the fabrication of a multi-layer circuit board as described above can be performed using the conventional method disclosed, for example, in U.S. Pat. No. 6,395,329. The thickness of the power conductive layer is preferably formed up to 6 times thicker than the thickness of the signal routing conductive layer, for heat diffusion purposes.

While the electrically conductive layers are sometimes illustrated by reference to copper, other materials may be used including aluminum and suicides such as tungsten silicide.

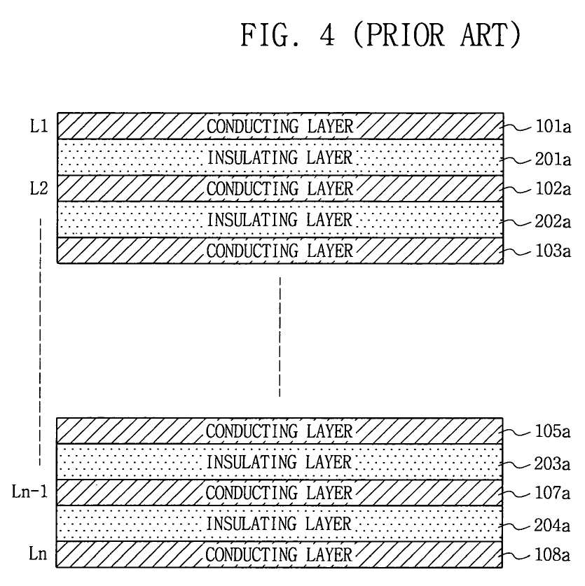

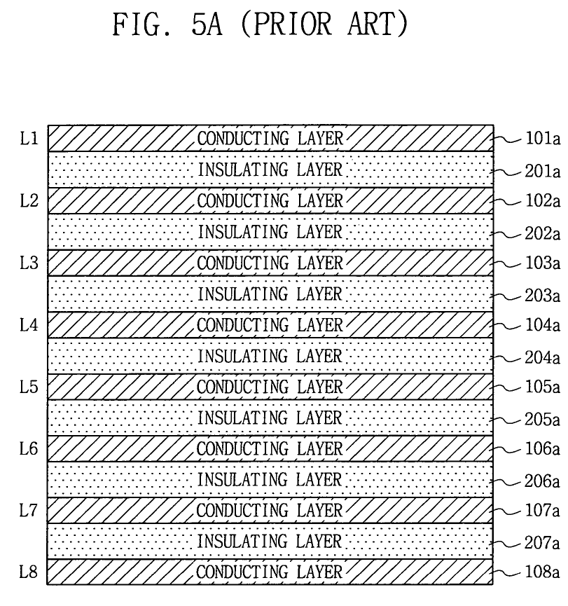

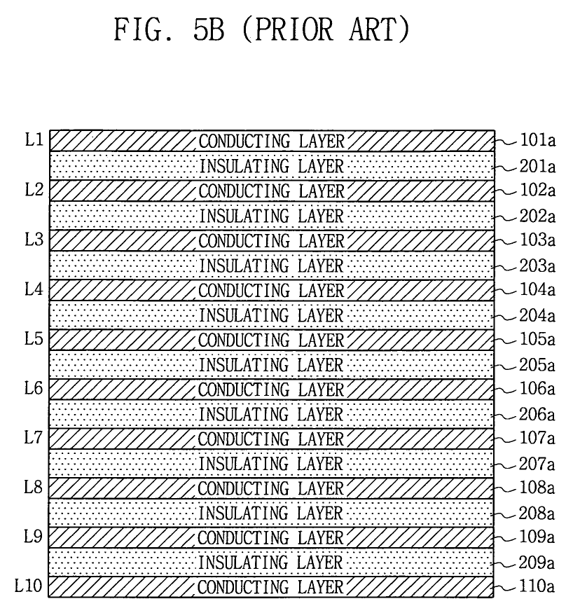

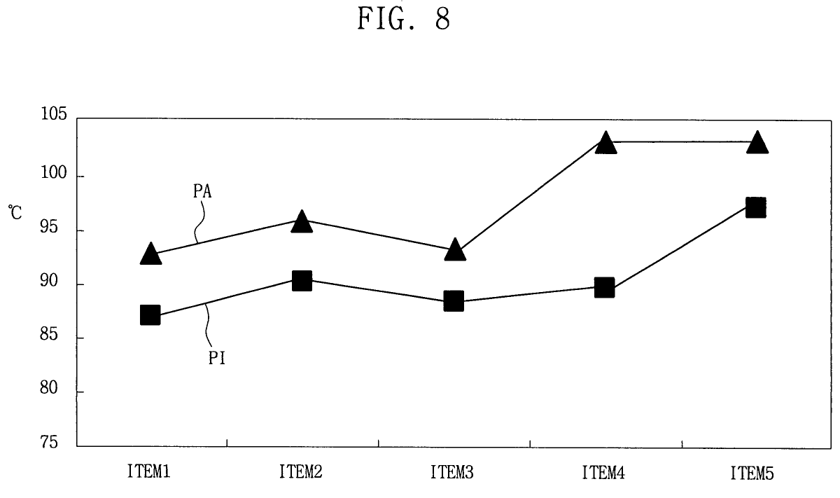

FIG. 8 is a graph of data illustrating the effect according to the structure of FIG. 6 in comparison with the structure of FIG. 4. In the drawing, the transverse axis represents five measurement items, and the longitudinal axis represents temperature (° C.). ITEM1 to ITEM3 among the measurement items refer to heat generation tests for DRAM chips, which operate through each of the test programs, and ITEM4 and ITEM5 refer to heat generation tests for active devices such as an operational amplifier, or the like. The test was performed on a printed circuit substrate having a DDR DRAM module, which operates at 200 MHz, mounted thereon. The device was inside a chamber maintained at a temperature of about 50° C. In the drawing, PI is a graph corresponding to the embodiment of the present invention, and PA is a graph according to the prior art. Since the embodiment of the present invention showed relatively low temperatures, when measuring the surface temperature of the device element in every item, it was concluded that the present embodiment of the invention indicated improved heat diffusion over that embodiment of the prior art.

As a result, it can be concluded that the thermal conductivity can be improved if one or more of the power layers is (are) formed thicker than the signal routing layer. As such, by changes of the thickness of the inner layers without the modification of the multi-layer nature of the circuit board structure, or in some cases the signal routing layer(s), the heat generated from the electronic parts mounted on the multi-layer circuit board can be effectively dissipated.

According to the present invention as described above, the heat diffusion performance of a multi-layer circuit board can be considerably improved in comparison with a conventional circuit board structure. Therefore, the present invention provides advantages including minimizing or reducing sizes of heat diffusion parts separate from the layers of the circuit board of a multi chip module. Further, the present invention can be structured without mounting of a heat diffuser separate from or external to the layers of the circuit board.

While the present invention has been particularly shown and described with reference to exemplary embodiments thereof and by referring to drawings, it will be understood by those of ordinary skill in the art that various changes in form and details may be made therein without departing from the spirit and scope of the present invention as defined by the following claims. For example, the number of the inner layers, and the position of the relatively thick inner layer can be modified in various forms without departing from the spirit of the present invention. Likewise the relatively thicker layers may be the signal routing layers rather than the power conductive layers. Further, in the case that a heat diffuser is installed, it can be significantly reduced in size, or the installation of the heat spreader can be omitted. Further, a multi-layer circuit board of a multi chip module was illustrated in the embodiment, but the present invention can be also employed in a printed circuit board.

1. A multi-layer circuit board having a stacked-layer structure, comprising:
an outer layer:
a first inner layer; and
a second inner layer, which comprises the same material as the first inner layer,
a third layer disposed between said first and second inner layers, the third inner layer comprising a different material than said first and second inner layers;
wherein the first inner layer and the second inner layer have a different thickness from each other.

2. The multi-layer circuit board according to claim 1, wherein the outer layer, the first inner layer, and the second inner layer comprising an electrically conductive material.

3. The multi-layer circuit board according to claim 1, wherein the first inner layer is thicker than the second inner layer.

4. The multi-layer circuit board according to claim 1, wherein said thicker layer is a VDD layer.

5. The multi-layer circuit board according to claim 1 further comprising an external heat diffuser.

6. A multi-layer circuit board comprising:
an outer layer composed of a conductive material;
a first inner layer composed of a conductive material; and
a second inner layer composed of a conductive material,
wherein the first inner layer's continuous cross sectional thickness is greater than the second inner layer's continuous cross sectional thickness.

7. A multi-layer circuit board comprising:
an outer layer comprising a conductive material;
a first inner layer comprising a conductive material; and
a second inner layer comprising a conductive material,
wherein the first inner layer's minimum thickness is greater than the second inner layer's minimum thickness.

8. The multi-layer circuit board according to claim 4, wherein the first inner layer is disposed closer to the outer layer than the second inner layer.

9. The multi-layer circuit board according to claim 8, wherein the first inner layer is disposed closer to the nearest outer layer than the second inner layer is disposed to the nearest outer layer.

10. The multi-layer circuit board according to claim 4, wherein the first inner layer is a power conductive layer, and the second inner layer is a signal routing layer.

11. A multi-layer circuit board comprising:
a first outer layer composed of a conductive material;
a first inner layer composed of a conductive material;
a second inner layer composed of a conductive material;
a second outer layer composed of a conductive material;
a third inner layer composed of a conductive material; and
a fourth inner layer composed of a conductive material,
wherein the first inner layer is thicker than the second inner layer, and the fourth inner layer is thicker than the third inner layer.

12. The multi-layer circuit board according to claim 11, wherein the first inner layer and fourth inner layer are disposed substantially symmetrical about the center of the layers of the multi-layer circuit board.

13. A multi-layer circuit board comprising:
a first inner layer for transmitting power; and
a second inner layer for transmitting signals,
wherein the first inner layer is thicker than the second inner layer.

14. The multi-layer circuit board according to claim 13, wherein the first inner layer is thicker than the second inner layer by a factor of about two or more.

15. A multi-layer circuit board comprising:
a first inner layer for transmitting power;
a second inner layer for transmitting signals;
a third inner layer for transmitting signals; and
a fourth inner layer for transmitting power,
wherein the first inner layer is thicker than the second inner layer, and the fourth inner layer is thicker than the third inner layer.

16. A method of fabricating a multi-layer circuit board comprising:
forming a first inner layer, comprising a conductive material, with a predetermined thickness; and
forming a second inner layer, comprising a conductive material, with a thickness smaller than that of the first inner layer.

17. A printed circuit board having a memory module mounted thereon comprising:
an outer layer;
a first inner layer; and
a second inner layer comprising the same material as the first inner layer,
wherein the first inner layer and the second inner layer have different thicknesses.

18. The printed circuit board according to claim 17, wherein the outer layer, the first inner layer, and the second inner layer comprising a conductive material.

19. The printed circuit board according to claim 17, wherein the first inner layer and the second inner layer are comprised of a conductive material.

20. The printed circuit board according to claim 17, wherein the first inner layer is thicker than the second inner layer.

21. A printed circuit substrate having a memory module mounted thereon comprising:
an outer layer comprised of a conductive material;
a first inner layer comprised of a conductive material; and
a second inner layer comprised of a conductive material,
wherein the first inner layer is thicker than the second inner layer.

22. A multi-layer circuit board structure configured such that insulating layers and interconnection conductive layers are alternately stacked, wherein
among the interconnection conductive layers, at least one inner interconnection conductive layers, is of a different thickness than at least one other inner conductive layer which are disposed under an outer interconnection conductive layer having a main surface on which circuit elements are capable of being mounted.

23. The multi-layer circuit board structure according to claim 22, wherein the inner interconnection conductive layers comprise power conductive layers and signal routing conductive layers.

24. A multi-layer circuit board structure configured such that insulating layers and interconnection conductive layers are alternately stacked, wherein
the interconnection conductive layers comprise:
a top interconnection conductive layer having a main surface to which circuit elements are operatively connected;
a bottom interconnection conductive layer facing the top interconnection conductive layer;
an inner power conductive layer, having a predetermined thickness, disposed between the top interconnection conductive layer and the bottom interconnection conductive layer; and
an inner signal routing conductive layer, having a thickness less than that of the inner power conductive layer, disposed between the inner power conductive layer and the bottom interconnection conductive layer.

25. The multi-layer circuit board structure according to claim 24, wherein the insulating layers are prepreg layers, and the interconnection conductive layers are copper layers.

26. A method of fabricating a multi-layer circuit board configured such that insulating layers and interconnection conductive layers are alternately stacked, comprising forming inner interconnection conductive layers between outer conductive layers, wherein at least one inner interconnection conductive layers is formed thicker than at least one other inner interconnection conductive layers, thereby improving heat spreading performance of the multi-layer circuit board.

27. The method according to claim 20, wherein the inner interconnection conductive layers are comprised of copper, and comprise power conductive layers and signal routing conductive layers.

28. The method according to claim 27, wherein thicknesses of the power conductive layers is greater than those of the signal routing conductive layers.

29. A multi-layer circuit board structure configured such that insulating layers and interconnection conductive layers are alternately stacked, wherein
the interconnection conductive layers comprise:
a top interconnection conductive layer having a main surface on which circuit elements are capable of being mounted;
a bottom interconnection conductive layer as a bottom surface layer facing the top interconnection conductive layer;
an inner power conductive layer having a first predetermined thickness, disposed between the top interconnection conductive layer and the bottom interconnection conductive layer, with insulating layers interposed between the top and bottom interconnection conductive layers; and
an inner signal routing conductive layer disposed between the inner power conductive layer and the bottom interconnection conductive layer, having a second predetermined thickness greater than said first predetermined thickness.

30. The multi-layer circuit board structure according to claim 29, wherein the insulating layers are prepreg layers, and the interconnection conductive layers are copper.

31. The multi-layer circuit board structure according to claim 30, wherein the inner power conductive layers are copper layers for transmitting a power voltage or a ground voltage.

32. A multi-chip module structure having electronic circuit elements mounted thereon and using a multi-layer circuit board configured such that insulating layers and interconnection conductive layers are alternately stacked, comprising:
outer interconnection conductive layer having a main surface on which the electronic circuit elements are mounted;
inner interconnection conductive layers disposed under said outer interconnection conductive layer, wherein at least one thickness of an inner interconnection layer has a thickness different from at least one other inner interconnection layer;
a heat diffuser installed between a surface of a package of some of the electronic circuit elements and a surface of the multi-layer circuit board, for diffusing heat generated by operation of the electronic circuit elements out of the circuit board.

33. The multi-chip module structure according to claim 32, wherein the inner interconnection conductive layers comprise power conductive layers and signal routing conductive layers.

34. The multi-chip module structure according to claim 33, wherein a thickness of the power conductive layer is greater than that of the signal routing conductive layer.

35. The multi-chip module structure according to claim 33, wherein a thickness of the signal routing conductive layer is greater than that of the power conductive layer.

36. The multi-chip module structure according to claim 33, wherein the electronic circuit elements comprise at least DRAM chips.

37. A method of forming a multi-layered circuit board comprising:
determining the number of conductive and insulating layers in the multi-layered circuit board;
forming selected layers to be of a relatively different thickness than other layers.

38. The method of claim 37 wherein said selected layers of a relatively different thickness are insulating layers.

39. The method of claim 37 wherein said selected layers of a relatively different thickness are insulating layers.
